(19) United States
(12) Patent Application Publication
(10) Pub. No.: US 2012/0103396 A1
(43) Pub. Date: May 3, 2012

(54) Electrical Component Connection System And Method Of Use

(76) Inventors: Lintao Hu, Shanghai (CN); Xiaoqun Chen, Shanghai (CN); Chunfu Zhou, Shanghai (CN); Henry Ko, Taipei (TW)

(21) Appl. No.: 13/190,804

(22) Filed: Jul. 26, 2011

(30) Foreign Application Priority Data
Jul. 27, 2010 (CN) 201010244523.2

(51) Int. Cl. H01L 31/05; H01R 43/00; H01L 31/048

(52) U.S. Cl. 136/251; 29/825

(57) ABSTRACT

An electric connection system connecting adjacent BIPV glass panels and frames in a solar curtain wall. The electric connection system includes a first electrical connector, a second electrical connector, and a third electrical connector. The first electric connector is connected to an electrical component positioned in each of the adjacent BIPV glass panels, while the second electric connector is positioned in the frame and configured to mate with the first electric connector. The third electric connector electrically connects adjacent second electric connectors in adjacent frames with each other.

### CROSS-REFERENCE TO RELATED APPLICATIONS

This application claims the benefit of the filing date under 35 U.S.C. §119(a)-(d) of Chinese Patent Application No. CN 201010244523.2, filed Jul. 27, 2010.

### FIELD OF THE INVENTION

The invention relates to an electric connector system, and in particular, to an electric connection system for a solar curtain wall.

### BACKGROUND

It is well-known that solar energy is one kind of popular renewable energies. Attention has been directed toward the conversion of solar energy into electric energy, since it both provides electricity and decreases environmental pollution.

Building Integrated Photovoltaic (BIPV) technology, a new solar energy utilizing technology, aims to integrate the solar (photovoltaic) electrical generation products into some parts of the buildings, e.g., roof, windows, solar glass curtain walls, etc.. These integrated solar (photovoltaic) electrical generation products provide both rain and wind shielding. In the solar curtain wall, for example, electric connection between adjacent glasses is achieved through junction boxes in the conventional Building Integrated Photovoltaic (BIPV) technology. Presently, these junction boxes are directly secured to the glass of the solar curtain wall or secured to the periphery of the glass. However, in such installations, the junction boxes may have the following disadvantages. First of all, the junction boxes are directly exposed to the outside, since the junction boxes usually are provided outside the solar curtain wall and the solar curtain wall frame. Thus, the junction boxes may be easily damaged, e.g., by the execrable outdoor environmental factors, such as a windstorm and/or a rainstorm, which may cause damage to the whole photovoltaic system. Additionally, in view of a whole appearance of the solar curtain wall, the construction and placement of these junction boxes are un-aesthetic. In addition, the junction boxes are relatively complex in the installation and relatively high in the cost.

### SUMMARY

It will be advantageous to provide an electric connection system for connecting adjacent BIPV glass panels and frames in a solar wall curtain.

The electric connection system includes a first electrical connector, a second electrical connector, and a third electrical connector. The first electric connector is connected to an electrical component positioned in each of the adjacent BIPV glass panels, while the second electric connector is positioned in the frame and configured to mate with the first electric connector. The third electric connector electrically connects adjacent second electric connectors in adjacent frames with each other.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a perspective view of an electric connection system according to the invention;

FIG. 2 is a partial-enlarged perspective view of FIG. 1;

FIG. 3 is a perspective view of a first electric connector in the electric connection system according to the invention;

FIG. 4 is a perspective view of a second electric connector in the electric connection system according to the invention;

FIG. 5 is another perspective view of the second electric connector shown in FIG. 4;

FIG. 6 is perspective view of a third electric connector in the electric connection system according to the invention;

FIG. 7 is an exploded perspective view of an electric connection system positioned in a solar curtain wall according to the invention.

### DETAILED DESCRIPTION OF THE EMBODIMENT(S)

The embodiments of the present disclosure will be described hereinafter in detail with reference to the attached drawings, wherein the like reference numerals refer to the like elements. The present disclosure, however, should not be construed as being limited to the embodiment set forth herein; rather, these embodiments are provided so that the present disclosure will be thorough and complete, and will fully convey the concept of the disclosure to those skilled in the art.

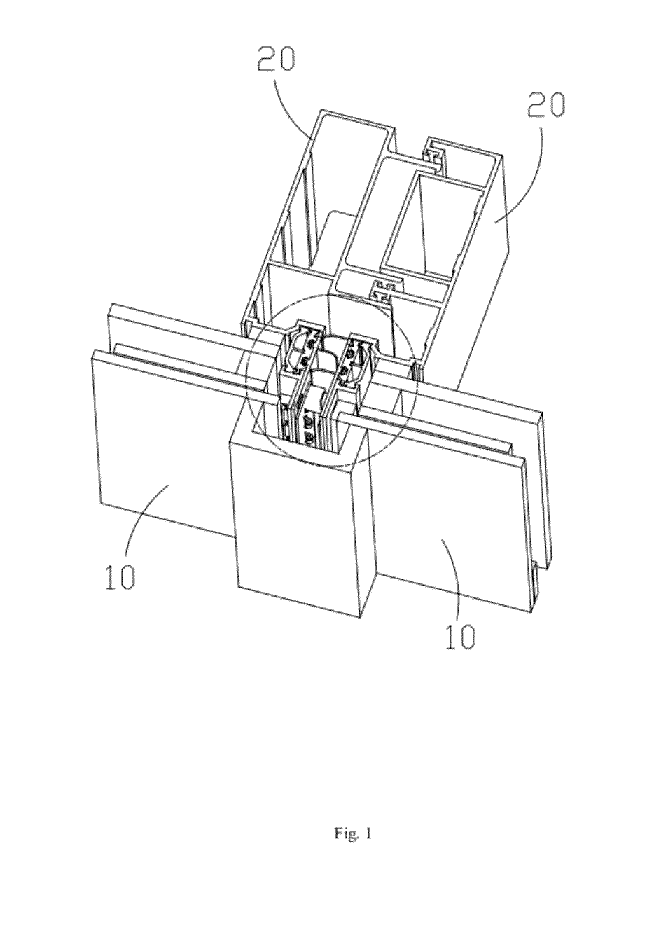

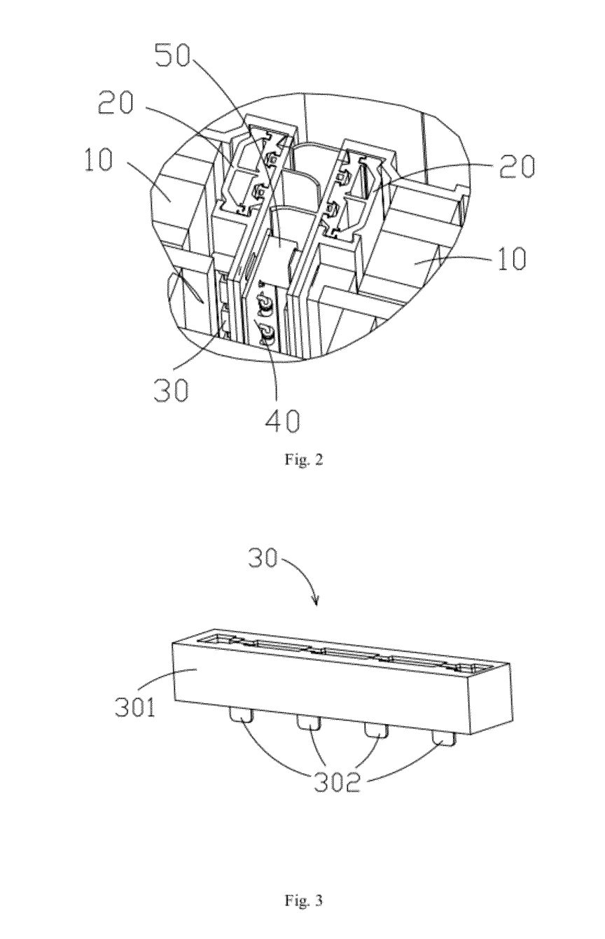

As shown in FIGS. 1-2, 7, an electric connection system is provided according an embodiment of the invention. The electric connection system is applied in a solar curtain wall for electric connection among adjacent BIPV glass panels panels 10 in the solar curtain wall including BIPV glass panels panels 10 and frames 20. The electric connection system at least includes a first electric connector 30, a second electric connector 40, and a third electric connector 50. The first electric connector 30 is connected to an electrical component 101 positioned in the BIPV glass panels panels 10. The second electric connector 40 is positioned in the frame 20 and configured to mating with the first electric connector 30. The second electric connectors 40 in the adjacent frames 20 are electrically connected with each other through the third electric connector 50.

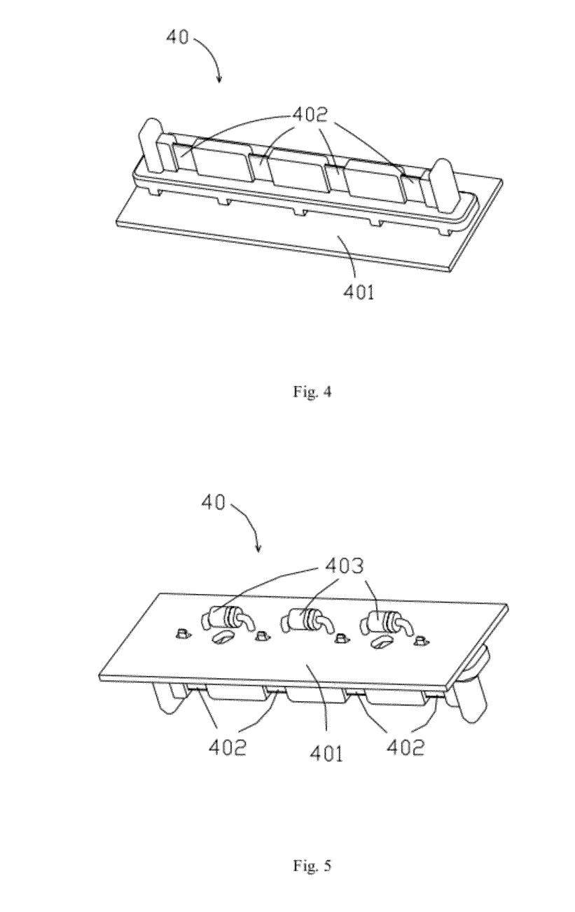

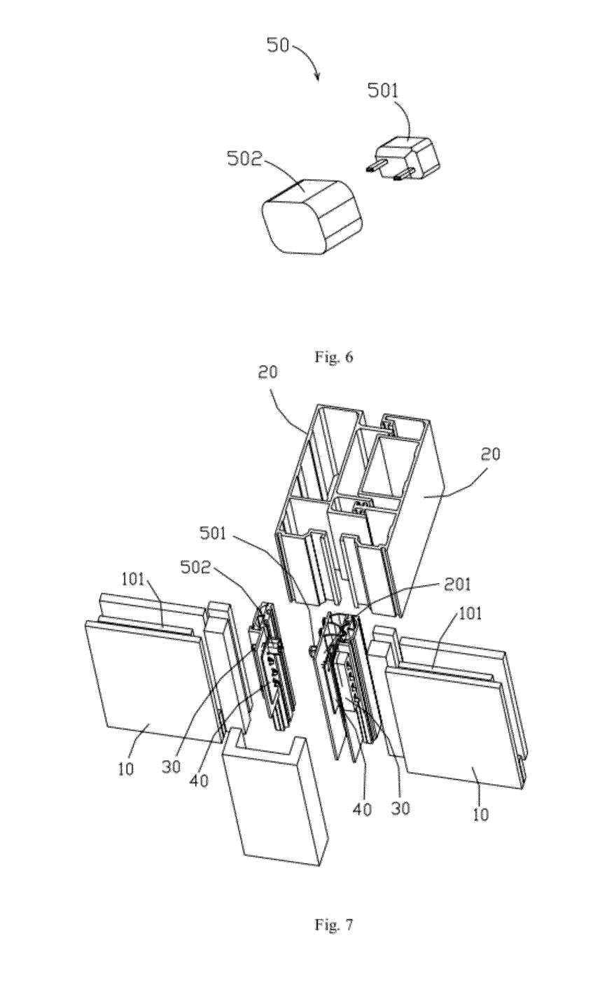

Specifically, as shown in FIGS. 3-7, the first electric connector 30 includes a housing 301 and a plurality of first electrically connecting terminals 302 positioned in the housing 301, particularly in FIG. 3. The second electric connector 40 includes a circuit board 401, a plurality of second electrically connecting terminals 402 positioned in the circuit board 401, and a plurality of diodes 403 each connecting with the adjacent second electrically connecting terminals 402. The respective first electrically connecting terminal 302 are configured for connecting the respective electrical component 101 in the BIPV glass panels panels with the respective second electrically connecting terminal 402, particularly in FIGS. 4 and 5. The third electric connector 50 is shown as a connector for power supply, which includes a male portion 501 positioned on the second electric connector 40 in one frame 20 and a female portion 502 positioned on the second electric connector 40 in another frame 20 adjacent to the one frame 20, which female portion 502 mates with the male portion 501, particularly in FIG. 6. Accordingly, electric connection between the adjacent BIPV glass panels panels 10 are achieved by mating the first, second and third electric connectors 30, 40, 50 in the electric connection system according to the invention. Specifically, the frame 20 includes an receiving portion 201 in which the second electric connector 30 is received. In the embodiment shown, the plurality of first electrically connecting terminals 302 in the first electric connector 30 and the electrical components 101 in the BIPV glass panels panels 10 are welded, respectively.

Meanwhile, a method for using such electric connection system is provided according to an embodiment of the invention. Specifically, as shown in FIGS. 1, 2 and 7, the method at least includes the steps of: (1) providing first, second, and third electric connectors 30, 40, 50, and providing the solar curtain wall including BIPV glass panels panels 10 and frames 20; (2) receiving the second electric connectors 40 in the receiving portion 201 of each frame 20; (3) electrically connecting the plurality of first electrically connecting terminals 302 in the first electric connector 30 with the electrical components 101 in the BIPV glass panels panels 10, respectively; (4) mating the second electric connector 40 in the frame 20 with the first electric connector 30 in the BIPV glass panels panels 10 when the BIPV glass panels panels 10 is secured onto the frame 20; and, (5) electrically connecting the second electric connectors 40 in the adjacent frames 20 through the third electric connector 50 for electric connection among adjacent BIPV glass panels panels 10. In the above-mentioned method, preferably, the plurality of first electrically connecting terminals 302 in the first electric connector 30 and the electrical components 101 in the BIPV glass panels panels 10 are welded with each other, respectively. In the embodiment shown, the electrical component 101 is a metal sheet with good electrically conducting characteristics.

In addition, as shown in FIGS. 1-7, a frame 20 with an electric connection performance is provided, which is applied on BIPV glass panels panels 10, according to one preferred embodiment of the present invention. Specifically, the frame at least comprises a frame body 20 and a second electric connector 40. The second electric connector 40 is disposed in the frame body 20 and is adapted for mating with a first electric connector 30 in the BIPV glass panels 10 to achieve an electric connection. The frame 20 further includes a receiving portion 201 in which the second electric connector 40 is received. The second electric connector 40 positioned in the frame 20 includes a circuit board 401, a plurality of second electrically connecting terminals 402 positioned in the circuit board 401, and a plurality of diodes 403 each connecting with the adjacent second electrically connecting terminals 402. The respective second electrically connecting terminal 402 is configured for connecting the respective first electrically connecting terminal 302 in the first electric connector 30, so as to achieve the electrical connection. It is worthy to mention that the first electric connector 30 may be temporarily connected to the second electric connector 40 in the frame 20 while the second electric connectors 40 on the adjacent frames 20 are connected through the connector 50 for power supply during the installation of the BIPV glass panels 10 onto the frame 20. In the embodiment shown, the frame 20 is made by aluminum materials.

As apparent form the above, the invention has at least the following advantages: the electric connection system according to the invention may be safely and effectively embedded in the frames of the solar curtain wall, such that the adjacent BIPV glass panels are effectively connected within in the solar curtain wall. Accordingly, the junction box used in the prior art may be successfully replaced by the electric connection system according to the invention so as to overcome the drawbacks like damage due to be exposure, aesthetics in the whole appearance, and relative high cost in the prior junction box construction.

Although several exemplary embodiments have been shown and described, it would be appreciated by those skilled in the art that various changes or modifications may be made in these embodiments without departing from the principles and spirit of the disclosure, the scope of which is defined in the claims and their equivalents. It will be understood that, the terms “includes” and/or “including”, when used herein, specify the presence of stated features, steps, and/or components, but do not preclude the presence or addition of one or more other features, steps, and/or components. Further, the singular forms “a”, “an” and “the” are intended to include the plural forms as well, unless the context clearly indicates otherwise. In addition, the reference numbers used in the claims are for the purpose of describing particular embodiments only and are not intended to be limiting of example embodiments of the invention.

Although several embodiments have been shown and described, it would be appreciated by those skilled in the art that various changes or modifications may be made in these embodiments without departing from the principles and spirit of the disclosure, the scope of which is defined in the claims and their equivalents.

What is claimed is:

1. An electric connection system for connecting adjacent BIPV glass panels and frames in a solar curtain wall, said electric connection system comprising:
a first electric connector connected to an electrical component positioned in each of the adjacent BIPV glass panels;
a second electric connector positioned in the frame and configured to mate with the first electric connector; and
a third electric connector electrically connectable adjacent second electric connectors in adjacent frames with each other.

2. The electric connection system according to claim 1, wherein the frame includes a receiving portion in which the second electric connector is received.

3. The electric connection system according to claim 1, wherein the first electric connector includes a housing and a plurality of first electrically connecting terminals positioned in the housing.

4. The electric connection system according to claim 3, wherein the second electric connector includes a circuit board, a plurality of second electrically connecting terminals positioned in the circuit board, and a plurality of diodes each connecting the plurality of second electrically connecting terminals.

5. The electric connection system according to claim 4, wherein the plurality of first electrically connecting terminals are configured for connecting the electrical components in each of the adjacent BIPV glass panels with the plurality of second electrically connecting terminals.

6. The electric connection system according to claim 5, wherein the third electric connector is a connector for a power supply.

7. The electric connection system according to claim 1, wherein the third electrical connector includes a male portion positioned on the second electric connector in one frame and a female portion positioned on the second electric connector in another frame adjacent to the one frame and configured to mate with the male portion.

8. The electric connection system according to claim 3, wherein the plurality of first electrically connecting terminals in the first electric connector is welded with the electrical components in each of the BIPV glass panels.

9. A method for using an electric connection system connecting adjacent BIPV glass panels and frames in a solar curtain wall, the method comprising the steps of:
providing a first electric connector that connects to an electrical component positioned in each of the adjacent BIPV glass panels;
providing a second electric connector positioned in the frame and configured to mate with the first electric connector; and
providing a third electric connector through which the second electric connector in adjacent frames are electrically connected with each other.

10. The method for using the electric connection system according to claim 9, the method further comprising the step of:
receiving the second electric connectors in a receiving portion of each adjacent frame;

11. The method for using the electric connection system according to claim 9, wherein the first electric connector includes a housing and a plurality of first electrically connecting terminals positioned in the housing.

12. The method for using the electric connection system according to claim 11, wherein the second electric connector includes a circuit board, a plurality of second electrically connecting terminals positioned in the circuit board, and a plurality of diodes each connecting the plurality of second electrically connecting terminals.

13. The method for using the electric connection system according to claim 12, wherein the plurality of first electrically connecting terminals are configured for connecting the electrical component in each of the adjacent BIPV glass panels with the plurality of second electrically connecting terminals.

14. The method for using the electric connection system according to claim 13, wherein the third electrical connector includes a male portion positioned on the second electric connector in one frame and a female portion positioned on the second electric connector in another frame adjacent to the one frame and configured to mate with the male portion.

15. The method for using the electric connection system according to claim 14, the method further comprising the step of:
electrically connecting the plurality of first electrically connecting terminals in the first electric connector with respective electrical components in each of the adjacent BIPV glass panels, respectively.

16. The method for using the electric connection system according to claim 15, the method further comprising the step of:
mating the second electric connector in the frame with the first electric connector in each of the adjacent BIPV glass panels when each of the adjacent BIPV glass panels are mounted onto the frame.

17. The method for using the electric connection system according to claim 14, the method further comprising the step of:
electrically connecting a plurality of second electric connectors in adjacent frames through the third electric connector.

18. A frame with an electric connection system applied to BIPV glass panels, the frame comprising:
a frame body; and
a second electric connector positioned in the frame body and configured to mate with a first electric connector positioned in each of the adjacent BIPV glass panels.

19. The frame according to claim 18, further comprising a receiving portion in which the second electric connector is received.

20. The frame according to claim 18, wherein the second electric connector includes a circuit board, a plurality of second electrically connecting terminals positioned in the circuit board, and a plurality of diodes each connecting the plurality of second electrically connecting terminals.

21. The frame according to claim 20, wherein the plurality of second electrically connecting terminals are adapted for connecting with a plurality of first electrically connecting terminals in the first electric connector.

22. The frame according to claim 21, wherein a plurality of second electric connectors in adjacent frames are connected through a connector for power supply.

23. The frame according to claim 18, wherein the frame is made of aluminum materials.
